(19) United States
(12) Patent Application Publication
(10) Pub. No.: US 2006/0060930 A1
(43) Pub. Date: Mar. 23, 2006

(54) Atomic layer deposition of high dielectric constant gate dielectrics

(76) Inventors: Matthew V. Metz, Hillsboro, OR (US); Clifford W. Boyd, Hillsboro, OR (US); Markus Kuhn, Portland, OR (US); Suman Datta, Beaverton, OR (US); Jack Kavalieros, Portland, OR (US); Mark L. Doczy, Beaverton, OR (US); Justin K. Brask, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 10/943,693

(22) Filed: Sep. 17, 2004

(51) Int. Cl. H01L 29/76; H01L 21/336

(52) U.S. Cl. 257/410; 257/411; 438/261; 438/591

(57) ABSTRACT

Gate dielectrics formed of silicates of hafnium or zirconium dioxide may be formed by atomic layer deposition. The precursors for the atomic layer deposition may include an oxidant, a silicate precursor, and a zirconium or hafnium precursor.

### BACKGROUND

This invention relates to the fabrication of MOS field effect transistors.

As transistors are continuing to scale or become smaller in size, gate leakage is becoming unacceptably high. Using smaller transistors means more complex operations can be done by lower cost devices.

One way to continue gate scaling while maintaining acceptable leakage is to use gate dielectrics with higher dielectric constants. These higher dielectric constant materials currently have limited use because of severe electron mobility degradation and unfavorable reactions with polysilicon (which may be utilized as the gate electrode in some cases). Thus, both with polysilicon and metal gate electrodes, high dielectric constant gate dielectrics may experience problems.

Thus, there is a need for better ways to form transistors.

### BRIEF DESCRIPTION OF THE DRAWINGS

FIG. 1 is an enlarged, cross-sectional view of one embodiment of the present invention;

FIG. 2 is a schematic depiction of an atomic layer deposition chamber in accordance with one embodiment of the present invention;

FIG. 3 is a depiction of an atomic layer deposition protocol in accordance with one embodiment of the present invention; and

FIG. 4 is an enlarged, cross-sectional view of a completed transistor in accordance with one embodiment of the present invention.

### DETAILED DESCRIPTION

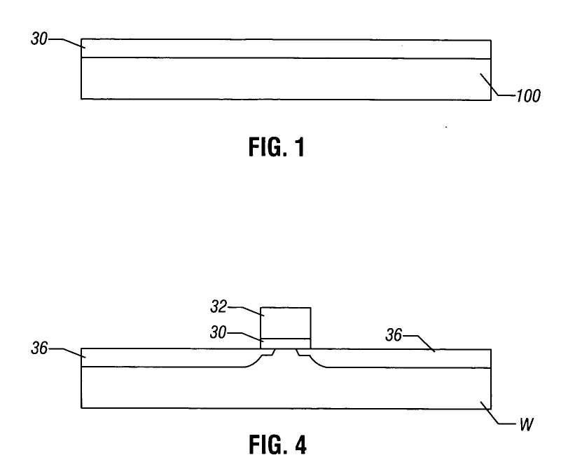

Referring to FIG. 1, a semiconductor substrate 100 may have a gate dielectric 30 formed thereon. In one embodiment of the present invention, the gate dielectric 30 may be formed of a higher dielectric constant material. As used herein, a higher dielectric constant material is a material having a dielectric constant greater than 10. Examples of suitable materials include hafnium silicate and zirconium silicate.

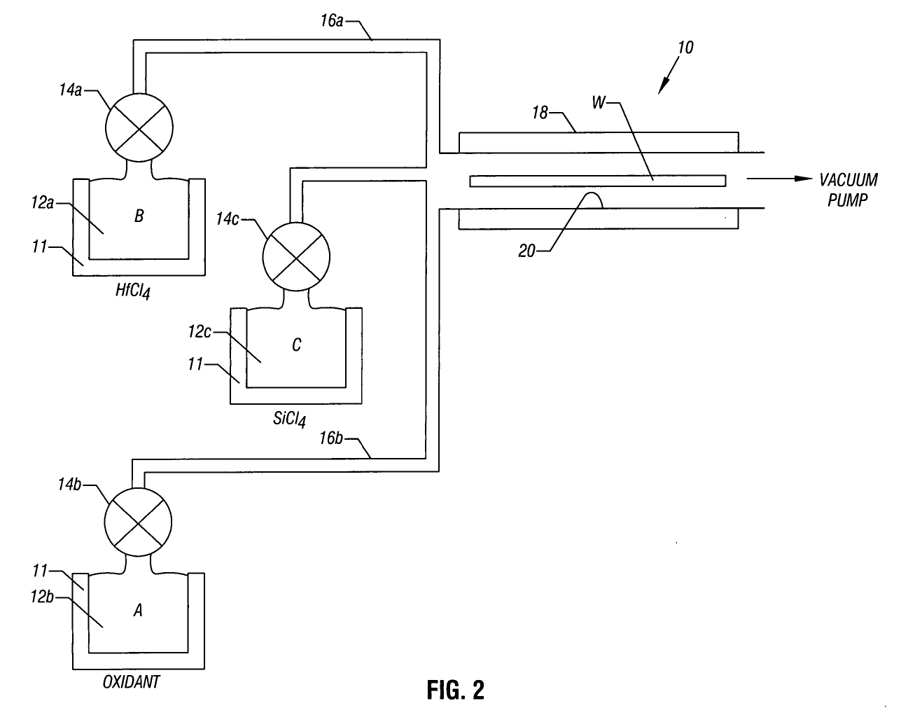

Referring to FIG. 2, the deposition of the gate dielectric 30 may be done in an atomic layer deposition chamber 10. The chamber 10 may have heaters 18 surrounding the chamber 20. A first precursor A may be contained in liquid form within a closed, pressurized, heated reservoir 12b. The liquid in the reservoir 12b is heated by a heater 11 to form a vapor. The injection of the precursor A, as a vapor, into the chamber 20 via the line 16b may be controlled by a high speed valve 14b. In one embodiment of the present invention, the reservoir 12b holds an oxidant such as water, hydrogen peroxide, or ozone.

A metal precursor B may be stored in a closed, pressurized, heated reservoir 12a. The metal precursor may, for example, be hafnium chloride (HfCl₄) in connection with forming a hafnium containing dielectric film. In another embodiment, the reservoir 12a may hold zirconium chloride. The reservoir 12a communicates with the chamber 20 via line 16a, whose flow is controlled by a high speed valve 14a. The precursor B may be a liquid that is converted to a vapor by the heater 11.

A silicon precursor C is contained within a reservoir 12c. The silicon precursor may be silicon chloride (SiCl₄). Again, the precursor C is also in liquid form but is released as a gas through the valve 14c upon heating by a heater 11 which surrounds the reservoir C. Thus, each of the reservoirs 12 may be heated by a heater 11. Each heater 11 may be controlled to produce the desired amount of vapor for injection into the chamber 20. Thus, the more heat that is applied, the more vapor that may result from any given reservoir 12.

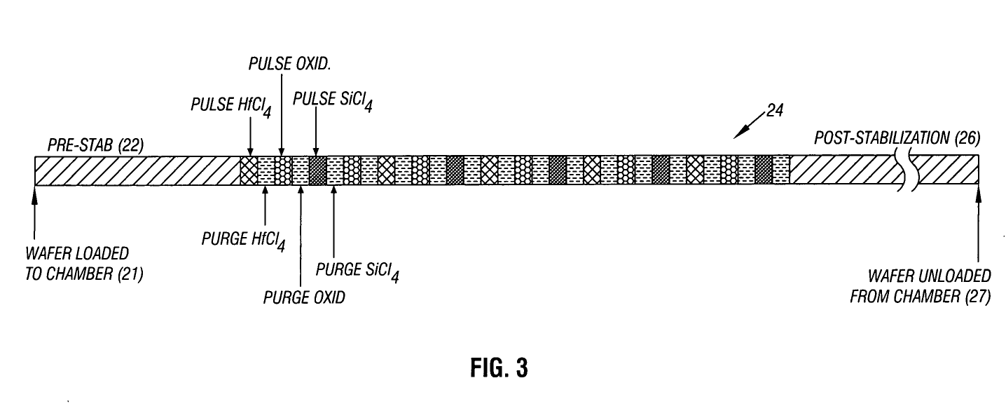

Referring to FIG. 3, in accordance with one embodiment of the present invention, the formation of the gate dielectric 30 may be accomplished using a sequence beginning with a prestabilization stage 22. The wafers are loaded into the chamber 20 as indicated as 21. Then, the chamber 20 may be heated by the heater 18 to a desired temperature. The heaters 11 may also be activated to ramp the reservoirs 12 to their target temperatures.

After the prestabilization stage 22, the metal precursor B, such as hafnium chloride, is vaporized and injected as a pulse into the chamber 20. The pulse length is set by the valve 14a. The metal precursor pulse may be followed by a purge cycle. In the purge cycle, the metal precursor gas that was previously applied is exhausted using a neutral gas such as nitrogen and a vacuum pump. The duration of the pulse and purge may be controlled as desired to achieve particular film thicknesses in particular situations.

After the purging of the precursor B, a pulse of oxidant, such as water, may be applied from reservoir 12b, followed by a purging of the oxidant. Next, a pulse of the precursor C, such as silicon chloride, may be applied, again followed by a purge pulse. Then, another oxidant pulse and another purge pulse are applied. This sequence of eight pulses in the specified order may be repeated to achieve a desired film thickness formed of monolayers built up by each pulse. A monolayer is a layer of material having the thickness of one molecule. In one embodiment, the sequence may be repeated three or four times. However, in other cases, the pulses are simply repeated until the desired thickness is achieved.

In one embodiment of the present invention, the chamber 20 reaches a temperature of approximately 200 to 400° C. during the prestabilization period. The temperature of the precursor B may be from about 150 to about 250° C. The temperature of the precursor C may be from about 10 to about 40° C. The temperature of the precursor A may be from approximately 10 to approximately 40° C. The temperature in the chamber 20 may be from about 200 to about 400° C. in one embodiment of the present invention.

Referring finally to FIG. 4, in one embodiment of the present invention, the finished device may have a gate electrode 32 over the gate dielectric 30 which has been patterned so that the gate electrode 32 and gate dielectric 30 may be used as a mask to form the source and drains 36. The gate electrode 32 may be polysilicon, a silicide, or a metal.

Examples of n-type metals for an n-type metal gate transistor include zirconium, hafnium, titanium, tantalum, aluminum, and their alloys including metal carbides that includes these elements, such as hafnium carbide, zirconium carbide, titanium carbide, tantalum carbide, and aluminum carbide.

Examples of p-type metal for forming p-type metal layers over a silicate of zirconium or hafnium dioxide include ruthenium, palladium, platinum, cobalt, nickel, and conductive metal oxides, including ruthenium oxide.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a silicate of zirconium or hafnium dioxide by applying pulses of oxidant, a silicon precursor, and a zirconium or hafnium precursor to an atomic layer deposition chamber.

2. The method of claim 1 including exposing a wafer to successive pulses of silicon precursor, oxidant, and zirconium or hafnium precursor and oxidant.

3. The method of claim 2 including repeatedly providing a sequence of pulses of oxidant, silicon precursor, and zirconium or hafnium precursor.

4. The method of claim 2 including successively providing a sequence of pulses, in order, of oxidant, silicate precursor, zirconium, or hafnium precursor and oxidant.

5. The method of claim 4 including providing said pulses in the sequence of oxidant, silicate precursor, zirconium, or hafnium precursor and oxidant and repeating said sequence until the desired thickness of silicate is formed.

6. The method of claim 1 including forming a metal gate electrode over said silicate.

7. The method of claim 1 including forming a polysilicon gate electrode over said silicate.

8. The method of claim 1 including forming a source and drain.

9. The method of claim 1 including purging after each pulse.

10. A semiconductor structure comprising:
a stack of monolayers of hafnium silicate.

11. The structure of claim 10 wherein said stack forms a gate dielectric.

12. The structure of claim 11 including a metal gate on said stack.

13. The structure of claim 11 including a polysilicon gate on said stack.

14. A semiconductor structure comprising:
a series of stacked monolayers of zirconium silicate.

15. The structure of claim 14 wherein said stack forms a gate dielectric.

16. The structure of claim 15 including a metal gate on said stack.

17. The structure of claim 15 including a polysilicon gate on said stack.

18. A semiconductor structure comprising:
a substrate;
a gate dielectric formed of monolayers of zirconium or hafnium silicate; and
a gate electrode over said monolayers.

19. The structure of claim 18 wherein said gate electrode is formed of polysilicon.

20. The structure of claim 19 wherein said gate electrode is formed of metal.
